(19) United States
(12) Patent Application Publication
(10) Pub. No.: US 2015/0087252 A1
(43) Pub. Date: Mar. 26, 2015

(54) ELECTRONIC DEVICE AND METHOD FOR PERFORMING A RADIO CHANNEL CONNECTION

(71) Applicant: Samsung Electronics Co., Ltd., Gyeonggi-do (KR)

(72) Inventors: Haemin PARK, Gyeongsangbuk-do (KR); Yonggil HAN, Gyeongsangbuk-do (KR); Hyejung KIM, Gyeongsangbuk-do (KR)

(73) Assignee: Samsung Electronics Co., Ltd.

(21) Appl. No.: 14/491,449

(22) Filed: Sep. 19, 2014

(30) Foreign Application Priority Data
Sep. 24, 2013 (KR) 10-2013-0113063

(51) Int. Cl. H04H 40/18; H03J 7/02

(52) U.S. Cl. CPC H04H 40/18; H03J 7/02
USPC 455/186.1

(57) ABSTRACT

In a method and an electronic device for performing a radio channel connection are provided. The method includes detecting tuning in to a specific radio channel; determining whether there is pre-stored broadcasting information; determining, if the pre-stored broadcasting information exists, whether the specific radio channel is found in the pre-stored broadcasting information; and using, if the specific radio channel is found in the pre-stored broadcasting information, at least one of the pre-stored broadcasting information and a contents server address corresponding to the specific radio channel.

### PRIORITY

This application claims priority under 35 U.S.C. §119(a) to a Korean patent application filed on Sep. 24, 2013 in the Korean Intellectual Property Office and assigned Serial No. 10-2013-0113063, the entire content of which is incorporated herein by reference.

### BACKGROUND OF THE INVENTION

1. Field of the Invention

The present invention relates generally to radio channel connection, and more specifically, to an electronic device and a method for performing a radio channel connection using broadcasting information in the electronic device.

2. Description of the Related Art

Some current electronic devices include a hybrid radio capable of using analog information and digital information together. Such an electronic device may obtain information (e.g., a radio national code, program IDentification (ID) information, and frequency information) from an analog broadcast and transmit the obtained information to a radio Domain Name System (DNS) server. Then the electronic device may obtain a contents server address from the radio DNS server and thereby use digital information (e.g., RadioVIS information, RadioEPG information, RadioTAG information). When a certain radio station operates two or more different radio channels, a radio DNS server and a contents server may have the same address.

Unfortunately, typical techniques for obtaining information using a hybrid radio have a drawback of requiring frequent access to the radio DNS server whenever the electronic device tunes in to a specific radio channel so as to acquire digital information.

### SUMMARY OF THE INVENTION

The present invention has been made to address the above problems and disadvantages, and to provide at least the advantages described below. Accordingly, an aspect of the present invention provides an electronic device and related method for a radio channel connection using broadcasting information that contains therein a contents server address and a radio server address.

According to an aspect of the present invention, a method for a radio channel connection of an electronic device using broadcasting information is provided. The method includes detecting tuning in to a specific radio channel; determining whether there is pre-stored broadcasting information; determining, if the pre-stored broadcasting information exists, whether the specific radio channel is found in the pre-stored broadcasting information; and using, if the specific radio channel is found in the pre-stored broadcasting information, at least one of the pre-stored broadcasting information and a contents server address.

According to another aspect of the present invention, a method for a radio channel connection of an electronic device using broadcasting information is provided. The method includes creating, in response to a channel search event, a frequency list by scanning radio frequencies; determining whether there is pre-stored broadcasting information; determining, if the pre-stored broadcasting information is present, whether a specific frequency is found in the pre-stored broadcasting information; and using, if the specific frequency is found in the pre-stored broadcasting information, at least one of the pre-stored broadcasting information and a contents server address.

According to another aspect of the present invention, an electronic device is provided. The electronic device includes a communication unit configured to receive a radio broadcast; an audio unit configured to convert the radio broadcast into an audio signal; and a control unit configured to detect tuning in to a specific radio channel, to determine whether there is pre-stored broadcasting information, to determine, if the pre-stored broadcasting information is present, whether the specific radio channel is found in the pre-stored broadcasting information, and if the specific radio channel is found in the pre-stored broadcasting information, and to use at least one of the pre-stored broadcasting information and a contents server address corresponding to the specific radio channel.

### BRIEF DESCRIPTION OF THE DRAWINGS

The above and other aspects, features and advantages of the present invention will be more apparent from the following detailed description in conjunction with the accompanying drawings, in which:

FIG. 1 is a block diagram illustrating an electronic device in accordance with an embodiment of the present invention.

FIG. 2 is a flow diagram illustrating a method for a radio channel connection in an electronic device in accordance with an embodiment of the present invention.

FIG. 3 is a flow diagram illustrating a method for a radio channel connection in an electronic device in accordance with another embodiment of the present invention.

### DETAILED DESCRIPTION OF EMBODIMENTS OF THE PRESENT INVENTION

Hereinafter, embodiments of the present invention are described in detail with reference to the accompanying drawings. The following description includes various specific details to assist in that understanding but these are to be regarded as mere examples. Accordingly, those of ordinary skill in the art will recognize that various changes and modifications of the embodiments described herein can be made without departing from the scope and spirit of the present invention. In addition, descriptions of well-known functions and constructions may be omitted for clarity and conciseness.

The terms and words used in the following description and claims are not limited to their dictionary meanings, but are merely provided to enable a clear and consistent understanding of the present invention. Accordingly, the following description of various embodiments of the present disclosure is provided for illustration purposes, and not for the purpose of limiting the scope of present invention.

It is to be understood that the singular forms “a,” “an,” and “the” include plural referents unless the context clearly dictates otherwise. Thus, for example, reference to “a signal” includes reference to one or more of such signals.

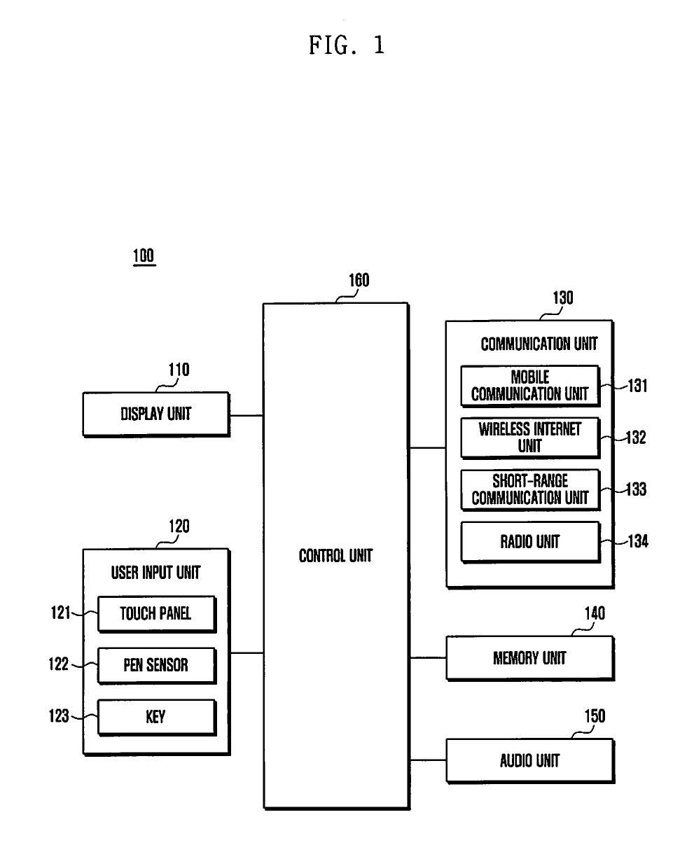

FIG. 1 is a block diagram illustrating an electronic device 100 in accordance with an embodiment of the present invention.

The electronic device 100 herein may be applied to, for example, a smart phone or any other variety of devices including a mobile phone, a tablet Personal Computer (PC), a hand-held PC, a laptop PC, a Portable Multimedia Player (PMP), a Personal Digital Assistant (PDA), and a wearable device such as a wrist watch or a Head-Mounted Display (HMD).

Referring to FIG. 1, the electronic device 100 may include, but is not limited to, a display unit 110, a user input unit 120, a communication unit 130, a memory unit 140, an audio unit 150, and a control unit 160.

The display unit 110 visually outputs images or other data to a user. The display unit 110 may include a display panel, which may be formed of, for example, a Liquid Crystal Display (LCD), an Active Matrix Light Emitted Diode (AMOLED) display, or other such displays. The display unit 110 may further include a controller configured to control such a display panel. The display panel may be realized in a flexible, transparent or wearable form.

Additionally, the display unit 110 may be provided in the form of a touch screen by being integrated with a touch panel 121. For example, the touch screen may be designed as an integrated module in which the display panel and the touch panel are combined with each other in a stack structure.

According to an embodiment of the present invention, the display unit 110 may display, as a user interface, music service information associated with a location, time or playback list under the control of the control unit 160.

The user input unit 120 may receive various commands from a user. The user input unit 120 may include, for example, but not limited to, at least one of the touch panel 121, a pen sensor 122, and a key 123.

The touch panel 121 may recognize a user's touch input through any of various sensing techniques, including well-known types of sensing techniques, such as a capacitive type, a resistive type, an infrared type, an ultrasonic type, or other such techniques. The touch panel 121 may further include therein a controller (not shown). Meanwhile, when the touch panel 121 utilizes a capacitive type technique, the touch panel 121 may have a proximity sensing capability in addition to a touch detecting capability. Additionally, the touch panel 121 may further include therein a tactile layer. In this case, the touch panel 121 may offer a tactile feedback to a user.

The pen sensor 122 may be formed of, for example, a special sheet for recognizing a pen in the same way as recognizing a user's touch input.

The key 123 may have a mechanical key and/or a touch key. The mechanical key may include, but is not limited to, at least one of a power button disposed on the lateral side of the electronic device 100 and used to turn on or off the electronic device 100, a volume button disposed on the lateral side of the electronic device 100 and used to adjust a volume, and a home button disposed on the front side of the electronic device 100 and used to invoke a home screen. The touch key may include, but is not limited to, at least one of a menu key disposed on the front side of the electronic device 100 and used to offer a menu associated with currently displayed content, and a return key disposed on the front side of the electronic device 100 and used to return to the previous screen.

The communication unit 130 may include therein, but is not limited to, at least one of a mobile communication unit 131, a wireless internet unit 132, a short-range communication unit 133, and a radio unit 134.

The mobile communication unit 131 transmits or receives a wireless signal to or from a base station, a server in a mobile communication network and/or any other device. Such a wireless signal may include a voice call signal, a video call signal, or various types of data associated with a text or multimedia message.

The wireless internet unit 132 accesses a wireless internet. Wireless internet techniques may employ Wireless Local Area Network (WLAN), also known as Wi-Fi, Wireless BROadband (Wibro), World Interoperability for Microwave Access (WIMAX), High Speed Downlink Packet Access (HSPDA), and other such techniques.

The short-range communication unit 133 performs short-range communication. Short-range communication techniques may employ Bluetooth, Radio Frequency IDentification (RFID), Infrared Data Association (IrDA), Ultra WideBand (UWB), ZigBee, and other such techniques.

The radio unit 134 receives an analog radio broadcast through access to a radio channel according to a frequency list stored in the memory unit 130.

Additionally, the communication unit 130 may further include (not shown) a network interface (e.g., a Local Area Network (LAN) card) or modem for connecting the electronic device 100 with a network (e.g., Internet, LAN, Wide Area Network (WAN), a telecommunication network, a cellular network, a satellite network, Plain Old Telephone Service (POTS), etc.).

The communication unit 130 may obtain a contents server address through access to a radio Domain Name System (DNS) server, and the electronic device 100 may also obtain broadcasting information from such a contents server address. Specifically, if an analog radio broadcast (e.g., a Frequency Modulation (FM) radio) is received through the radio unit 134, the electronic device 100 may receive, as metadata of the received analog radio broadcast, a wireless service identifier for access to the radio DNS server. This wireless service identifier may contain a radio national code, program ID information, and frequency information, which are required for access to the radio DNS server.

The communication unit 130 may access the radio DNS server indicated by the wireless service identifier and then receive a contents server address to be used for receiving digital information such as RadioVIS information and RadioEPG information. Under the control of the control unit 160, the electronic device 100 may store, in the memory unit 140, the contents server address obtained through the communication unit 130. Further, the electronic device 100 may obtain broadcasting information from the contents server address.

RadioVIS information specifies visual information (e.g., text and graphics) associated with a radio program, such as a news item, travel information, an IP-connected advertisement, or any other information. RadioEPG information specifies an address of internet streaming service, a broadcasting schedule, or any other equivalent.

The electronic device 100 may store the obtained broadcasting information in the memory unit 140 under the control of the control unit 160. This broadcasting information may have an eXtensible Markup Language (XML) Schema Instance (XSI) file format and contain therein information about all radio services and content addresses provided by the corresponding radio station.

Also, the communication unit 130 may access a contents server to receive digital information such as RadioVIS and RadioEPG.

The memory unit 140 may include at least one of an internal memory and an external memory.

The internal memory may include at least one of a volatile memory (e.g., Dynamic Random Access Memory (RAM) (DRAM), Static RAM (SRAM), Synchronous DRAM (SDRAM), etc.), a nonvolatile memory (e.g., One-Time Programmable Read Only Memory (OTPROM), Erasable and Programmable ROM (EPROM), Electrically Erasable and Programmable ROM (EEPROM), a mask ROM, a flash ROM, etc.), a Hard Disk Drive (HDD), and a Solid State Drive (SSD). According to an embodiment of the present invention, the control unit 160 may process commands or data received from the nonvolatile memory or any other element by loading them onto the volatile memory. Also, the control unit 160 may preserve data created or received from any other element in the nonvolatile memory.

The external memory may include, for example, at least one of Compact Flash (CF), Secure Digital (SD), Micro-SD, Mini-SD, eXtreme Digital (XD), and a memory stick.

The memory unit 140 may store therein an operating system for controlling resources of the electronic device 100, a program for the operation of an application, and the like. The operating system may include a kernel, a middleware, an Application Programming Interface (API), etc. A well known operating system such as Android, iOS, Windows, Symbian, Tizen, or Bada may be used.

The kernel may include a resource manager for managing a system resource, and a device driver. The resource manager may be composed of, for example, a control unit manager, a memory unit manager, a file system manager, etc., and may control, allocate, or retrieve a system resource. The device driver may control various elements of the electronic device 100 through access by software. For this control, the device driver may be composed of an interface and an individual driver module provided by each hardware manufacturer. The device driver may include, for example, at least one of a display driver, a camera driver, a Bluetooth driver, a share memory driver, a Universal Serial Bus (USB) driver, a keypad driver, a Wi-Fi driver, an audio driver, and an Inter-Process Communication (IPC) driver.

The middleware may be formed of a plurality of modules configured in advance to offer a particular function required in common by various applications. The middleware may offer a commonly required function through the API, in order for an application to effectively use limited system resources in the electronic device 100. The middleware may include, for example, at least one of an application manager, a window manager, a multimedia manager, a resource manager, a power manager, a database manager, and a package manager. Additionally, the middleware may include at least one of a connectivity manager, a notification manager, a location manager, a graphic manager, and a security manager. Further, depending on embodiments, a runtime library or any other library module may be included. The runtime library is a library module used by a compiler to add a new function through a programming language while an application is running. For example, the runtime library may perform specific functions regarding input/output, memory management, arithmetic function, or the like. The middleware may create a new middleware module by combining various functions of the above-described internal element modules. Meanwhile, in order to provide differentiated functions, the middleware may offer a specialized module for each operating system.

The API is a set of API programming functions and may have different configurations depending on the operating system. For example, when using Android or iOS, a single API set may be provided for each platform. When using Tizen, two or more API sets may be provided.

An application may perform at least one particular function using a related program. Applications may be classified into, for example, a preloaded application and a third-party application. For example, a home application may be used to invoke, for example, a home screen, a dialer application, a Short Message Service (SMS) or Multimedia Message Service (MMS) application, an Instant Message (IM) application, a browser application, a camera application, an alarm application, a contacts or address book application, a voice dialing application, an email application, a calendar application, a media player, an album application, a clock application, etc.

The memory unit 140 may store therein broadcasting information and a list of scanned frequencies. Additionally, the memory unit 140 may store therein a mapping relation between the broadcasting information and the frequency list. Under the control of the control unit 160, the electronic device 100 may store the obtained contents server address and/or broadcasting information in the memory unit 140.

The audio unit 150 may perform conversion between an audio signal and an electric signal. For example, the audio unit 150 includes at least one of a speaker, a receiver, an earphone, and a microphone, and may perform conversion of input and/or output audio signals.

According to an embodiment of the present invention, when the electronic device 100 accesses a radio channel through the communication unit 130, the audio unit 150 may convert a radio broadcast into audio signals according to the received information and then output the converted audio signals.

According to an embodiment of the present invention, the electronic device 100 may further include a camera unit (not shown), which can capture an image or record a video. The camera unit may include one or more image sensors (e.g., a front lens and/or a rear lens), an Image Signal Processor (ISP), and/or a flash LED. Additionally, the camera unit may include at least part of the control unit 160. For example, in addition to obtaining an image, the camera unit may correct the obtained image or calculate features of the image. In this case, the camera unit may be a functional module composed of a hardware module and a software module.

The control unit 160 may drive an operating system and programs, control various hardware and software components connected thereto, and perform a processing of various data including multimedia data. The control unit 160 may be formed of, e.g., a System on Chip (SoC), and may further have a Graphic Processing Unit (GPU).

When accessing an analog broadcast through the communication unit 130, the control unit 160 obtains a wireless service identifier contained in metadata of the analog broadcast. Using this identifier, the control unit 160 accesses a radio DNS server through the communication unit 130, obtains a contents server address from the radio DNS server, and stores the obtained address in the memory unit 140. The control unit 160 may obtain broadcasting information from the obtained contents server address. Additionally, using the obtained address, the control unit 160 may access a contents server and then receive digital information.

According to an embodiment of the present invention, when tuning in to a specific radio channel is detected, the control unit 160 determines whether there is pre-stored broadcasting information. If there is pre-stored broadcasting information, the control unit 160 further determines whether the specific radio channel is found in the pre-stored broadcasting information. If the specific radio channel is found in the pre-stored broadcasting information, the control unit 160 connects with the specific radio channel or receives digital information from a contents server by using the broadcasting information and a contents server address. Tuning in to the specific radio channel includes an automatic tuning and/or a manual tuning.

If there is no pre-stored broadcasting information, or if the specific radio channel is not found in the pre-stored broadcasting information, the control unit 160 accesses a radio DNS server of the specific radio channel and then obtains a contents server address from the radio DNS server through the communication unit 130. Using the obtained contents server address, the electronic device 100 accesses a contents server through the communication unit 130. Then the control unit 160 may receive digital information from the contents server through the communication unit 130. Meanwhile, if the specific radio channel is found in the pre-stored broadcasting information, the control unit 160 may create a mapping relation between the radio channel and an associated contents server by using the broadcasting information and the contents server address. This broadcasting information may have an XSI file format and contain therein information about all radio services and content addresses provided by the corresponding radio station.

According to another embodiment of the present invention, the control unit 160 detects a channel search event and then scans radio frequencies through the communication unit 130. Further, using the result of such a radio frequency scan, the control unit 160 creates a frequency list and stores the created frequency list in the memory unit 140.

Then the control unit 160 determines whether there is pre-stored broadcasting information and further determines whether a specific frequency is found in the pre-stored broadcasting information. If the specific frequency is found in the pre-stored broadcasting information, the control unit 160 uses the broadcasting information and a contents server address. Then the control unit 160 determines whether the contents server address is checked in the frequency list containing all scanned frequencies as well as in the specific frequency. If there is any non-checked frequency in the frequency list, the control unit 160 re-determines whether there is pre-stored broadcasting information and whether such a frequency is found in the pre-stored broadcasting information.

If there is no pre-stored broadcasting information, or if the specific frequency is not found in the pre-stored broadcasting information, the control unit 160 accesses a radio DNS server of the specific frequency and then obtains a contents server address from the radio DNS server through the communication unit 130. The electronic device 100 obtains broadcasting information from the obtained contents server address. Meanwhile, if any specific frequency is found in the pre-stored broadcasting information, the control unit 160 may create a mapping relation between a radio channel and an associated contents server by using the broadcasting information and the contents server address. This broadcasting information may have an XSI file format and contain therein information about all radio services and content addresses provided by the corresponding radio station.

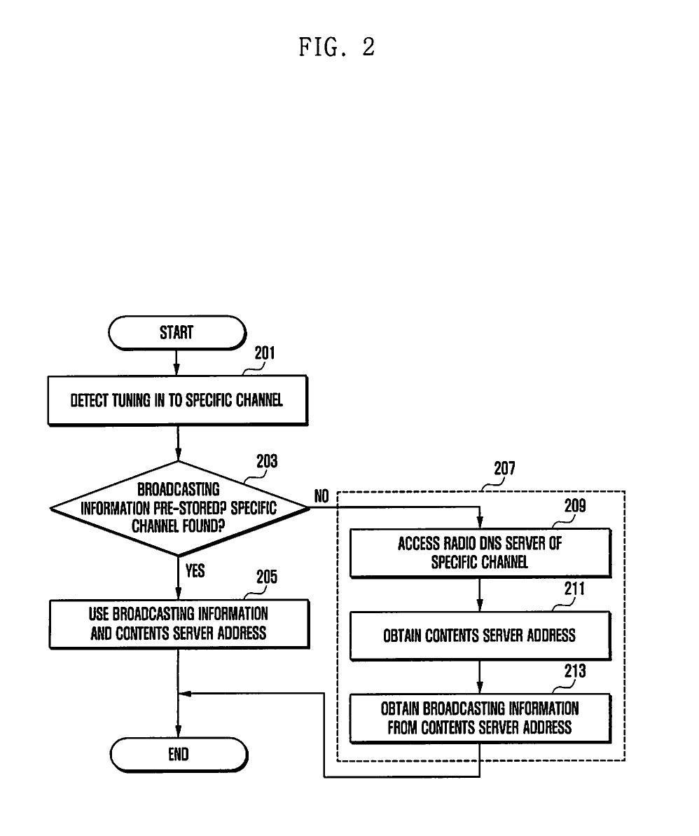

FIG. 2 is a flow diagram illustrating a method for a radio channel connection in the electronic device 100 in accordance with an embodiment of the present invention.

Referring to FIGS. 1 and 2, at step 201, the electronic device 100 detects tuning in to a specific radio channel.

At step 203, the electronic device 100 determines whether there is pre-stored broadcasting information and, if so, further determines whether the specific radio channel is found in the pre-stored broadcasting information.

If the specific radio channel is found in the pre-stored broadcasting information, the electronic device 100 uses at least one of the broadcasting information and a contents server address at step 205. Namely, if the specific radio channel is found in the pre-stored broadcasting information, the electronic device 100 connects with the specific radio channel or receives digital information from a contents server by using the broadcasting information and the contents server address.

If there is no pre-stored broadcasting information, or if the specific radio channel is not found in the pre-stored broadcasting information, at step 207 the electronic device 100 accesses a radio DNS server, obtains a contents server address, and obtains broadcasting information.

Specifically, if there is no pre-stored broadcasting information, or if the specific radio channel is not found in the pre-stored broadcasting information, the electronic device 100 accesses the radio DNS server of the specific radio channel at step 209. Then, at step 211, the electronic device 100 obtains the contents server address from the radio DNS server. Further, the electronic device 100 may create a mapping relation between the radio channel and an associated contents server by using the broadcasting information. At step 213, the electronic device 100 obtains the broadcasting information from the obtained contents server address. This broadcasting information may have an XSI file format and contain therein information about all radio services and content addresses provided by the corresponding radio station.

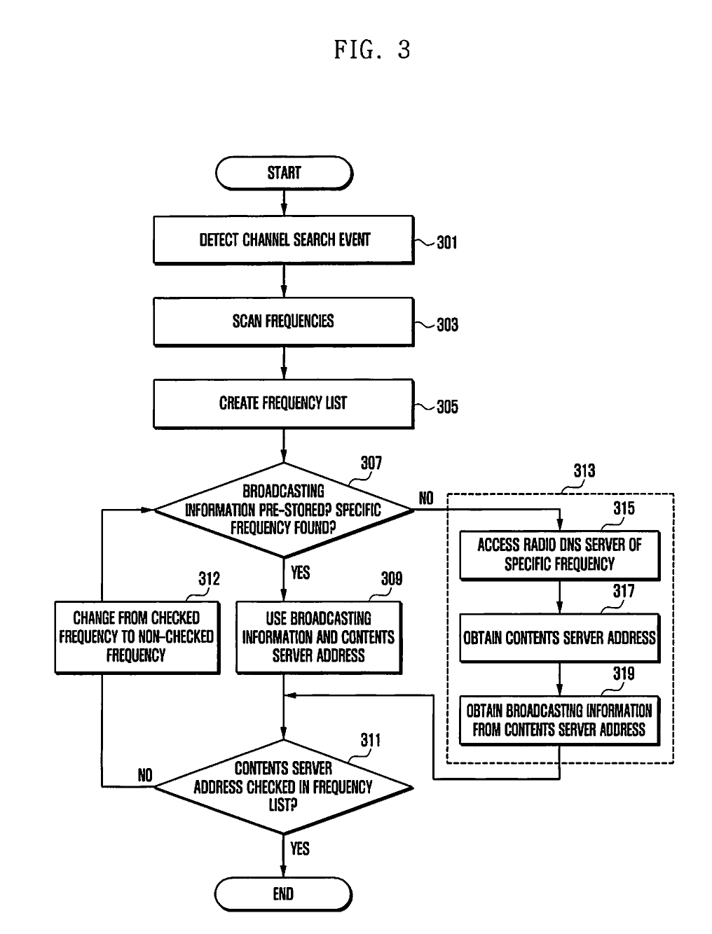

FIG. 3 is a flow diagram illustrating a method for a radio channel connection in the electronic device 100 in accordance with another embodiment of the present invention.

Referring to FIGS. 1 and 3, at step 301, the electronic device 100 detects a channel search event. Then the electronic device 100 scans radio frequencies at step 303. Further, using the result of such a radio frequency scan, the electronic device 100 creates a frequency list and stores therein the frequency list at step 305.

At step 307, the electronic device 100 checks a specific frequency in the frequency list by determining whether there is pre-stored broadcasting information and further determines whether the specific frequency is found in the pre-stored broadcasting information.

If the specific frequency is found in the pre-stored broadcasting information, the electronic device 100 uses at least one of the broadcasting information and a contents server address at step 309. Then, at step 311, the electronic device 100 determines whether the contents server address is checked in the frequency list containing all scanned frequencies as well as in the specific frequency. If there is any non-checked frequency in the frequency list, the electronic device 100 changes a specific frequency from the checked frequency to the non-checked frequency at step 312.

If there is no pre-stored broadcasting information, or if the specific frequency is not found in the pre-stored broadcasting information, at step 313 the electronic device 100 accesses a radio DNS server, obtains a contents server address, and obtains broadcasting information.

Specifically, if there is no pre-stored broadcasting information, or if the specific frequency is not found in the pre-stored broadcasting information, the electronic device 100 accesses the radio DNS server of the specific frequency at step 315. Then, at step 317, the electronic device 100 obtains a contents server address from the radio DNS server. Further, at step 319, the electronic device 100 obtains the broadcasting information from the obtained contents server address. The electronic device 100 may create a mapping relation between a radio channel and an associated contents server by using the broadcasting information. This broadcasting information may have an XSI file format and contain therein information about all radio services and content addresses provided by the corresponding radio station.

As fully discussed hereinbefore, the electronic device and related method for a radio channel connection disclosed herein can allow rapid access to a radio channel with reduced power consumption by using broadcasting information that contains therein a contents server address and a radio server address.

While the present invention has been particularly shown and described with reference to certain embodiments thereof, it will be understood by those skilled in the art that various changes in form and details may be made therein without departing from the spirit and scope of the invention, as defined by the appended claims and their equivalents.

What is claimed is:

1. A method for a radio channel connection of an electronic device using broadcasting information, the method comprising:
detecting tuning in to a specific radio channel;
determining whether there is pre-stored broadcasting information;
determining, if the pre-stored broadcasting information exists, whether the specific radio channel is found in the pre-stored broadcasting information; and
using, if the specific radio channel is found in the pre-stored broadcasting information, at least one of the pre-stored broadcasting information and a contents server address corresponding to the specific radio channel.

2. The method of claim 1, wherein the broadcasting information contains therein information about all radio services and content addresses provided by a radio station corresponding to the specific radio channel.

3. The method of claim 1, wherein using at least one of the pre-stored broadcasting information and the contents server address includes at least one of connecting with the specific radio channel and receiving digital information from a contents server corresponding to the contents server address.

4. The method of claim 1, further comprising:
accessing, if there is no pre-stored broadcasting information, or if the specific radio channel is not found in the pre-stored broadcasting information, a radio Domain Name System (DNS) server of the specific radio channel, obtaining a contents server address from the radio DNS server, obtaining the broadcasting information from the contents server address, and creating a mapping relation between the specific radio channel and an associated contents server indicated by the contents server address.

5. A method for a radio channel connection of an electronic device using broadcasting information, the method comprising:
creating, in response to a channel search event, a frequency list by scanning radio frequencies;
determining whether there is pre-stored broadcasting information;
determining, if the pre-stored broadcasting information is present, whether a specific frequency is found in the pre-stored broadcasting information; and
using, if the specific frequency is found in the pre-stored broadcasting information, at least one of the pre-stored broadcasting information and a contents server address.

6. The method of claim 5, wherein the broadcasting information contains therein information about all radio services and content addresses provided by a radio station corresponding to the specific frequency.

7. The method of claim 5, further comprising:
determining whether the contents server address is checked in the frequency list containing all scanned frequencies as well as in the specific frequency
re-determining, if there is a non-checked frequency in the frequency list, whether there is pre-stored broadcasting information and, if the pre-stored broadcasting information is present, whether the non-checked frequency is found in the pre-stored broadcasting information.

8. The method of claim 5, wherein using the pre-stored broadcasting information includes at least one of connecting with the specific frequency and receiving digital information from a contents server.

9. The method of claim 5, wherein using at least one of the pre-stored broadcasting information and the contents server address includes using both the pre-stored broadcasting information and the contents server address.

10. The method of claim 6, further comprising:
obtaining, if there is no pre-stored broadcasting information, or if the specific frequency is not found in the pre-stored broadcasting information, accessing a radio Domain Name System (DNS) server of the specific frequency, a contents server address from the radio DNS server, obtaining the broadcasting information from the contents server address, and creating a mapping relation between a specific radio channel and an associated contents server indicated by the contents server address.

11. An electronic device comprising:
a communication unit configured to receive a radio broadcast;
an audio unit configured to convert the radio broadcast into an audio signal; and
a control unit configured to detect tuning in to a specific radio channel, to determine whether there is pre-stored broadcasting information, to determine, if the pre-stored broadcasting information is present, whether the specific radio channel is found in the pre-stored broadcasting information, and if the specific radio channel is found in the pre-stored broadcasting information, and to use at least one of the pre-stored broadcasting information and a contents server address corresponding to the specific radio channel.

12. The electronic device of claim 11, wherein the broadcasting information contains therein information about all radio services and content addresses provided by a corresponding radio station.

13. The electronic device of claim 12, wherein the control unit is further configured to perform at least one of connecting with the specific radio channel and receiving digital information from a contents server corresponding to the contents server address by using the pre-stored broadcasting information.

14. The electronic device of claim 12, wherein the control unit is further configured to create a frequency list by scanning radio frequencies in response to a channel search event, to determine whether there is pre-stored broadcasting information and whether a specific frequency is found in the pre-stored broadcasting information, to use the pre-stored broadcasting information and a contents server address if the specific frequency is found in the pre-stored broadcasting information, and to determine whether the contents server address is checked in the frequency list containing all scanned frequencies as well as in the specific frequency.

15. The electronic device of claim 12, wherein the control unit is further configured to, if there is no pre-stored broadcasting information, or if the specific radio channel is not found in the pre-stored broadcasting information, to access a radio DNS (Domain Name System) server of the specific radio channel, to obtain a contents server address from the radio DNS server, to obtain the broadcasting information from the contents server address, and to create a mapping relation between the specific radio channel and an associated contents server indicated by the contents server address.

16. The electronic device of claim 14, wherein the control unit is further configured to, if there is no pre-stored broadcasting information, or if the specific frequency is not found in the pre-stored broadcasting information, to access a radio DNS (Domain Name System) server of the specific frequency, to obtain a contents server address from the radio DNS server, to obtain the broadcasting information from the contents server address, and to create a mapping relation between a specific radio channel and an associated contents server indicated by the contents server address.
